(19) United States
(12) Patent Application Publication
(10) Pub. No.: US 2019/0116693 A1
(43) Pub. Date: Apr. 18, 2019

(54) TEMPERATURE CONTROLLING DEVICE AND SYSTEM HAVING STATIC COOLING CAPACITY

(71) Applicant: CLEAR PX TECHNOLOGIES LTD, Yokneam Illit (IL)

(72) Inventors: Haim DROR, Tel Mond (IL); Atai ZIV, Matan (IL); Rabeeh KHOURY, Tarshisha (IL); Kossay OMARY, Nazareth (IL)

(21) Appl. No.: 16/090,250

(22) PCT Filed: Mar. 30, 2017
(86) PCT No.: PCT/IL17/50396

§ 371 Date: Sep. 30, 2018

Related U.S. Application Data
(60) Provisional application No. 62/316,048, filed on Mar. 31, 2016.

(51) Int. Cl. H05K 7/20

(52) U.S. Cl. CPC H05K 7/20836; H05K 7/20781

(57) ABSTRACT

A cooling device for cooling a heat generating load, the device having an enclosed housing defining a continuous cooling volume for flowing a coolant between an inlet and an outlet. The housing featuring at least one surface that is configured for facilitating heat exchange sequence with the heat generating load such that the coolant is configured to absorb generated heat.

### CROSS-REFERENCE TO RELATED APPLICATIONS

This application is a non-provisional of and claims priority of: U.S. provisional patent application Ser. No. 62/316,048 filed Mar. 31, 2016, entitled “SYSTEMS AND APPARATUS FOR REMOVING WASTE HEAT PRODUCED BY COMPUTER COMPONENTS AND IMPROVING PERFORMANCE THEREOF”, the contents of which are incorporated herein by reference as if set fully set forth herein.

### FIELD OF THE INVENTION

The present invention relates to a cooling device, system for cooling a heat producing load, and in particular, to such a device, system and method in which electronic components may be efficiently cooled utilizing a cooling liquid.

### BACKGROUND OF THE INVENTION

The use of a cooling liquid to cool electrical components small and large, for example in the form of data centers has been proposed. However the use of cooling by circulation of piped water and/or air is limited in that it does not sufficiently cool the large amount of heat produced. The cost of cooling is continuously increasing due to the increasing dependency on high performance electronics and the continuously growing need for instant availability of information. Accordingly processing needs are continuously increasing therefore increasing the need for effective cooling system of processing electronics.

However, current cooling systems do not provide efficient cooling for processing heavy environments such as large data centers.

Air conditioning systems, cooling fins, piped coolants, have been used to cool data centers and electronic components by delivering cool air to the processing compartments or similarly providing for circulating air or a cooling liquid via piping to the processing components that produce heat during use. Such cooling systems are described in the following publications: PCT Publication No. WO2015017737 to KEKAI et al., US Patent Publication No. US2014/0123492 to Cambpell et al., US Patent Publication No. US2015/0296659 to Desiano et al., U.S. Pat. No. 8,885,335 to Magarelli, U.S. Pat. No. 7,564,685 to Clidaras et al., U.S. Pat. No. 7,719,837 to Wu et al., U.S. Pat. No. 8,130,497 to Kondo et al., US Patent Publication No. 2008/0055855 to Kamath et al., US Patent Publication No. 2015/0083368 to Lyon, US Patent Publication No. 2009/0009958 to Pflueger, US Patent Publication No. 2013/0155607 to Wei.

### SUMMARY OF THE INVENTION

Present day processing demand is such that it renders an associated cooling system a critical system to allow for continued operation of the cooling system. That is, due to the high processing demands many data centers and the like processing heavy environments require continuous cooling to ensure that the data center remains operational. The cooling requirement is such that it renders the cooling system itself a critical system. Maintaining continuous operation of a cooling system without any downtime is costly in terms of energy expended, maintenance and money required.

The present invention overcomes the deficiencies of the background art by providing a cooling device and system for efficiently cooling a heat generating body, for example an electronic circuit or electronic component, or a data center. The present invention provides a highly efficient cooling system that is configurable such that the cooling system does not need to be maintained as a critical system while it maintains highly efficient cooling performance even during a cooling system downtime.

In embodiments the cooling device and system may be customized and/or designed so as to maintain sufficient cooling functions during an unplanned and/or unexpected and/or nonscheduled downtime period, without requiring the costs associated with rendering the cooling system a critical system.

Embodiments of the present invention provide a cooling device and/or system that may be configured to provide continuous cooling of a heat generating load, such as a processing device or data center, for a controllable and/or predetermined period of time, in particular during an unplanned and/or unexpected and/or nonscheduled downtime, such as a power outage.

In embodiments, the device according to embodiments of the present invention defines a housing featuring a large volume of a flowing coolant liquid that is utilized to cool a heat generating body and/or load associated therewith, wherein the flowing cooling liquid provides for effectively cooling the heat generating body and/or load even during an unplanned and/or unexpected and/or nonscheduled downtime, such as a power outage when the coolant is in a static non-flowing state.

Accordingly embodiments of the present invention provide a cooling device and system exhibiting both kinetic-active cooling when a coolant is actively flowing and static cooling when the coolant is in a non-flowing state. In embodiments the system is customizable and/or configurable so as to control the system performance in both kinetic cooling and static cooling.

In embodiments the system is configurable to provide cooling by controlling at least one or more parameters for example including but not limited to: the heat generating load associated with the system; the functional temperature range required by the heat generating load associate with the cooling system; required static cooling capacity; required minimal static cooling time; required static cooling temperature range; functional temperature range; minimum temperature; maximum temperature; coolant flow rate; coolant type; non-circulation time frame; any combination thereof, or the like.

In embodiments, the cooling device may be configured to flow a large volume of a coolant having a high specific heat capacity. Preferably, the volume of coolant liquid is configured so as to provide maximal cooling performance relative to the type and/or form of the heat generating load that is to be cooled.

The cooling-liquid may for example include but is not limited to a liquid selected from the group consisting of double distilled water, natural water, sea-water, fresh-water, recycled water, filtered water, or the like water based liquid. Optionally the coolant may be provided in any form of a flowing fluid for example including but not limited to at least one or more of: a liquid, a chemical, a compound, a substance having high heat capacity, a high heat capacity liquid, high heat capacity plasma, high heat capacity emulsion, high heat capacity viscous fluid, gas, high heat capacity mixture, high heat capacity colloid, the like or any combination thereof.

In embodiments, the selected coolant and the volume of the coolant may be dependent on the coolant's heat capacity.

Embodiments of the present invention provide a cooling device comprising an enclosed housing having a surface defining an enclosed continuous cooling volume; wherein a coolant, for example water, flows with the use of a coolant circulating interface featuring an inlet and an outlet, wherein at least a portion of the surface is provided from a high heat conducting material defining a heat exchanging surface; the housing comprises a coupling interface module for facilitating coupling at least one of body that is to be cooled onto the heat exchanging surface, so as to enable a heat conduction pathway comprising the body, the heat exchanging surface, and the coolant. Most preferably the cooling volume is customizable and/or configurable so as to determine the static cooling capacity of the device defined when the coolant is in a static non-flowing state.

In embodiments the device may comprise at least one and more preferably a plurality of liquid free zones. In embodiments, a plurality of liquid free zones may be arranged in a manner so as to provide maximal cooling performance.

In embodiments, the body to be cooled may be generating heat either directly or indirectly.

In embodiments, the cooling volume is configured to be proportional to the amount of heat generated directly or indirectly by the body.

In embodiments the cooling volume is configured to be proportional to both the heat generated directly or indirectly by the associated body and the required minimal static cooling time.

In embodiments the coupling interface may be further fit with at least one or more position control module that is provided for controlling the proximity or the pressure applied between the body and the heat exchanging surface for improving heat conduction between the two surfaces.

In embodiments the heat exchanging surface and at least a portion of the body may comprise a high heat conducting material. Optionally the high heat conducting material may for example comprise but is not limited to at least one or more materials selected from: a metal, a metallic alloy, aluminum, an aluminum alloy, copper, a copper alloy, silver, silver alloy, gold, gold alloy, platinum, platinum alloy, nickel, nickel alloy, titanium alloy, titanium alloy, graphene, a polymer, polymeric alloys, shape memory materials, shape memory polymers, shape memory metallic alloys, electroactive polymers, magnetostrictive materials, photosensitive materials, materials sensitive to magnetic field, materials sensitive to an electric field, materials sensitive to electromagnetic radiation, materials sensitive to light, material sensitive to specific wavelength, or any combination thereof.

In embodiments wherein the device comprises smart materials the configuration of the heat exchanging surface and/or at least a portion of the body may be controllable to assume variable configuration depending on the material and application for which it is utilized. For example, the heat exchanging surface and/or at least a portion of the body may be configured to have at least two or more states and/or configuration, a first configuration for a first temperature range and a second configuration for a second temperature range. Preferably switching between a first and second configuration may be controllable and/or configurable based on the smart materials utilized. For example the configuration may be switched with the direct and/or indirect application of at least one or more selected from: heat, magnetic field, electromagnetic field, electric current, light, electromagnetic wavelength, pressure, the like or any combination thereof.

For example a first configuration may be a low surface area configuration employed during a first lower temperature range, below a threshold temperature, and a second configuration may be a high surface area configuration employed during a second “higher” temperature range exhibited by at least one of the body and/or heat exchange surface.

Smart materials that may exhibit controllable configuration may for example include but are not limited to shape memory materials, shape memory polymers, shape memory metallic alloys, electroactive polymers, magnetostrictive materials, photosensitive materials, materials sensitive to magnetic field, materials sensitive to an electric field, materials sensitive to electromagnetic radiation, materials sensitive to light, material sensitive to specific wavelength, material sensitive to pressure, piezoelectric materials, the like or any combination thereof.

In embodiments, the cooling device may be configured to comprise a housing having an external surface and an internal surface defining therebetween a continuous cooling volume wherein a coolant is circulated within the continuous cooling volume; wherein the coolant flows within the cooling volume with the aid of a coolant circulating interface featuring a coolant inlet and a coolant outlet; wherein the internal surface forms at least one or more internal volume chamber(s) having at least one open face; the chamber is configured to be a sealed liquid free zone for housing a moveable body; at least a portion of the moveable body is configured to be in continuous heat exchanging contact with at least a portion of the internal surface therein the moveable body provides for mediating a heat conduction sequence wherein heat generated directly or indirectly by the moveable body is conducted toward the internal surface and finally onto the coolant; wherein the static cooling capacity is controllable by configuring at least one of: the cooling volume and/or the internal volume chamber.

Embodiments of the present invention provides a cooling system including the cooling device according to optional embodiments that is further coupled to a coolant circulating system that provides for flowing the coolant with the coolant circulating interface so as to allow for flowing the coolant between the coolant inlet and the coolant outlet, therein providing the kinetic-cooling of the device.

Unless otherwise defined, all technical and scientific terms used herein have the same meaning as commonly understood by one of ordinary skill in the art to which this invention belongs.

The materials, methods, and examples provided herein are illustrative only and not intended to be limiting.

Implementation of the method and system of the present invention involves performing or completing certain selected tasks or steps manually, automatically, or a combination thereof. Moreover, according to actual instrumentation and equipment of preferred embodiments of the method and system of the present invention, several selected steps could be implemented by hardware or by software on any operating system of any firmware or a combination thereof. For example, as hardware, selected steps of the invention could be implemented as a chip or a circuit. As software, selected steps of the invention could be implemented as a plurality of software instructions being executed by a computer using any suitable operating system. In any case, selected steps of the method and system of the invention could be described as being performed by a data processor, such as a computing platform for executing a plurality of instructions.

### BRIEF DESCRIPTION OF THE DRAWINGS

The invention is herein described, by way of example only, with reference to the accompanying drawings. With specific reference now to the drawings in detail, it is stressed that the particulars shown are by way of example and for purposes of illustrative discussion of the preferred embodiments of the present invention only, and are presented in order to provide what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

In the drawings:

FIG. 1A-B are schematic block diagrams of an exemplary cooling device according to embodiments of the present invention;

FIG. 2A-D are a perspective view of a schematic illustration of an exemplary cooling device according to embodiments of the present invention;

FIG. 2E is a schematic block diagram of an exemplary cooling device forming a cooling system according to embodiments of the present invention;

FIG. 3A-E show schematic illustrations of a cooling device fit with a position control module according to embodiments of the present invention;

FIG. 4A-E are schematic illustrations of a various configuration of body configured for associating with the cooling device according to embodiments of the present invention;

FIG. 5A-D are schematic illustrations of a cooling device arrangement forming a data center rackmount according to embodiments of the present invention;

FIG. 6A is schematic illustrations of a cooling device arrangement forming a data center rackmount according to embodiments of the present invention; and

FIG. 6B is a schematic illustration showing heat distribution of a device arrangement according to embodiments of the present invention.

### DESCRIPTION OF THE PREFERRED EMBODIMENTS

The present invention provides a cooling device and system for efficiently cooling a heat generating body, for example an electronic circuit or electronic component, or a data center. The present invention provides a highly efficient cooling system that is configurable such that the cooling system does not need to be maintained as a critical system while it provides highly efficient cooling performance even during a cooling system downtime.

The present invention relates to a cooling device in particular, to such a device and system utilized to cool a heat generating load, more preferably electronic circuitry and/or components by providing a device housing capable of providing a large volume of a coolant in a liquid phase, the liquid adept at absorbing a large amount of heat produced by the load.

In particular embodiments of the present invention provide a cooling device capable of proving both kinetic cooling and static cooling. Kinetic cooling is provided while the coolant is actively flowing and/or circulated with an auxiliary coolant circulating system. Static cooling is provided when the coolant is not flowing and/or circulating for example during a cooling system down time. Accordingly, embodiments of the present invention provide a cooling device capable of maintaining its cooling function during an unplanned downtime, therein greatly reducing costs associated with the cooling system.

The device and system of the present invention therefore provides a device and system capable of limiting the temperature fluctuations experienced by a heat generating load housed within the device by providing efficient cooling in both kinetic cooling and static cooling.

Embodiments of the present invention further provide a device and system that may be utilized to provide a temperature controlled data center.

The principles and operation of the present invention may be better understood with reference to the drawings and the accompanying description. The following figure reference labels are used throughout the description to refer to similarly functioning components are used throughout the specification hereinbelow.

10 auxiliary control systems;

15 auxiliary circulating system;

20 cooling system intel;

22 cooling system outlet;

50 heat generating load;

55 blade server;

55i blade server interface;

100, 300 cooling device;

101 cooling system;

102 internal liquid free volume/cell;

104 external connecting interface module;

106 auxiliary devices;

105 coolant flowing interface;

105i coolant inlet (cold);

105o coolant outlet (hot);

107 insulating surface;

108 device housing;

108c cooling volume;

108i housing internal surface;

108e housing external surface;

108s internal surface area;

109 front face;

109c rackmount cover;

110 body;

110a body sliding movement;

110f planar body;

111 interspace/gap;

112 first face;

114 second face;

115 positioning module;

140 cooling liquid phase;

150 rackmount;

210 trapezoidal body;

210a first face;

210b second face;

210p trapezoidal prism body;

212 side walls;

214 first angle;

216 second angle;

300a first cooling device;

300b second cooling device;

302 device housing;

304 external surface;

306 cooling volume;

308 heat conducting surface;

310 coupling interface;

310n, b nut and bolt assembly;

312 construct coupling interface;

320 auxiliary support construct;

350 cooling assembly;

352 distance;

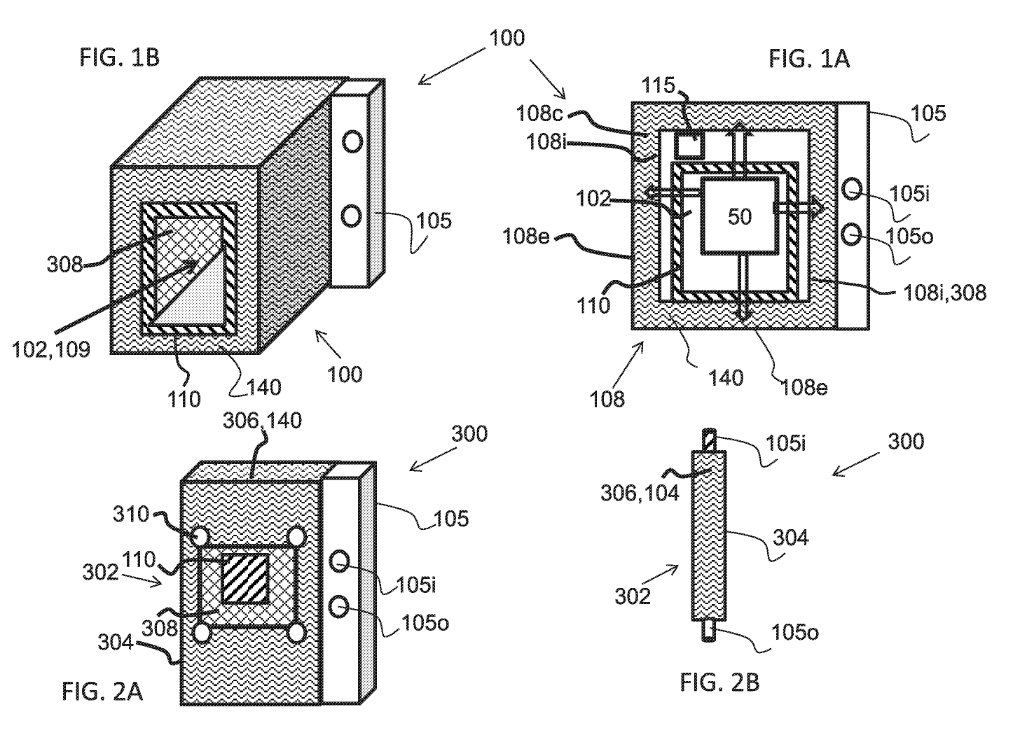

FIG. 1A-B that show a schematic block diagram illustration of an exemplary device 100 according to embodiments of the present invention for a temperature control and/or cooling device 100 that is used to maintain objects, for example body 110, associated therein within a predetermined temperature range.

FIG. 1A shows a face on view of device 100 and FIG. 1B shows a perspective view of device 100.

Device 100 provides temperature control by housing and/or associating with a heat generating body 110. Body 110 may be a direct heat producing body or an indirect heat producing body.

Within the context of this application the term “direct heat” refers to a heat generated directly by body 110.

Within the context of this application the term “indirect heat” refers to heat generated by a heat generating load 50 that is conveyed to a body 110 with which it is associated.

Temperature controlling device 100 comprises a cube-like housing 108 having an external surface 108e and an internal surface 108i that define between them a continuous enclosed cooling volume 108c. The continuous cooling volume 108c is configured to house a flowing fluid in the form of a coolant 140 that flows within the continuous volume 108c. Preferably coolant 140 flow within coolant volume 108c is facilitated with a coolant circulating interface 105 featuring an inlet 105i, for example in the form of a pipe and/or pipefitting, and an outlet 105o, for example in the form of a pipe and/or pipefitting. Preferably coolant volume 108c is a continuous volume for housing a coolant volume 140.

External surface 108e forms a cube-like enclosure having at least four surfaces, wherein at least one face 109 is provided as an open face. Optionally both front and back faces are provided as an open face.

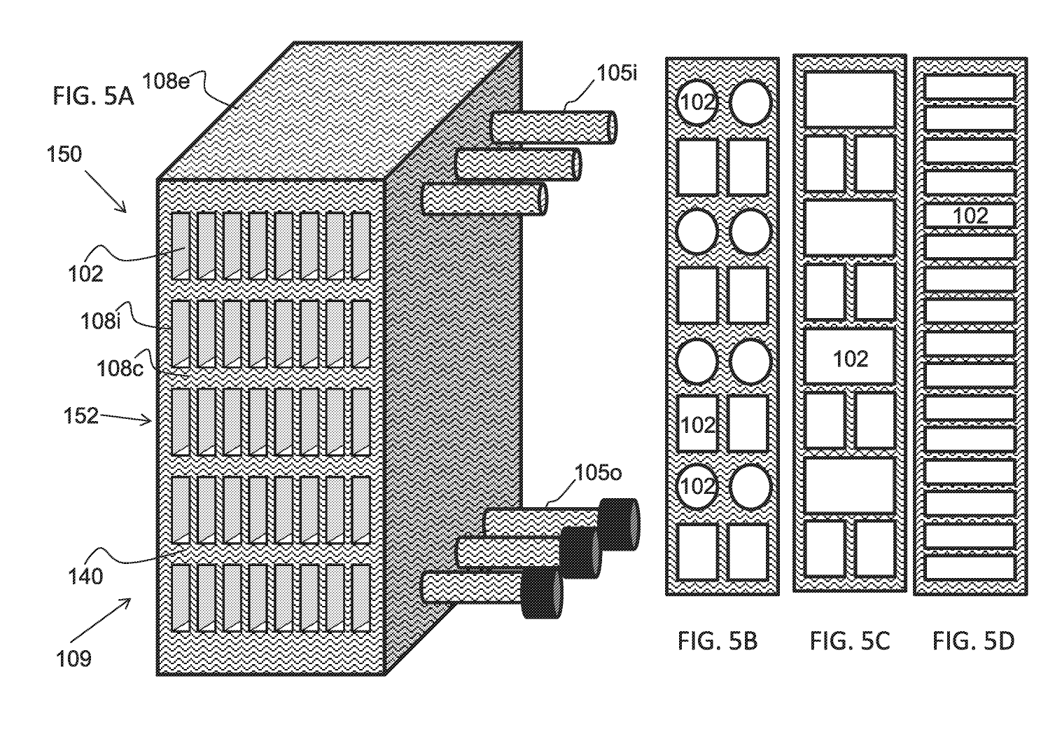

Internal surface 108i forms at least one internal volume chamber 102, shown in FIG. 1B, and more preferably a plurality of internal volume chambers 102, as shown in FIG. 5A-D. Internal volume chamber 102 is preferably surrounded by coolant volume 108c and coolant 140 disposed therein. Device 100 is configured such that the volume of coolant 140 closely surrounds chamber 102 and its contents most preferably body 110 therefore directly contributing to the temperature control properties of device 100, both in terms of kinetic cooling capacity and static cooling capacity.

Internal surface 108i is configured to form individual internal volume chambers 102 as a sealed liquid free zone. Chamber 102 forms a dry, liquid free environment internal to housing 108 that provides for receiving and housing a body 110 to be cooled and/or temperature controlled.

Most preferably at least a portion of internal surface 108i provides a heat exchange surface for facilitating heat conduction away from body 110 toward coolant 140. At least a portion of internal surface 108i provides a dedicated heat exchange surface 308, shown in FIG. 1B. Most preferably body 110 is in heat exchange contact with at least a portion of internal surface 108i and/or heat exchange surface 308.

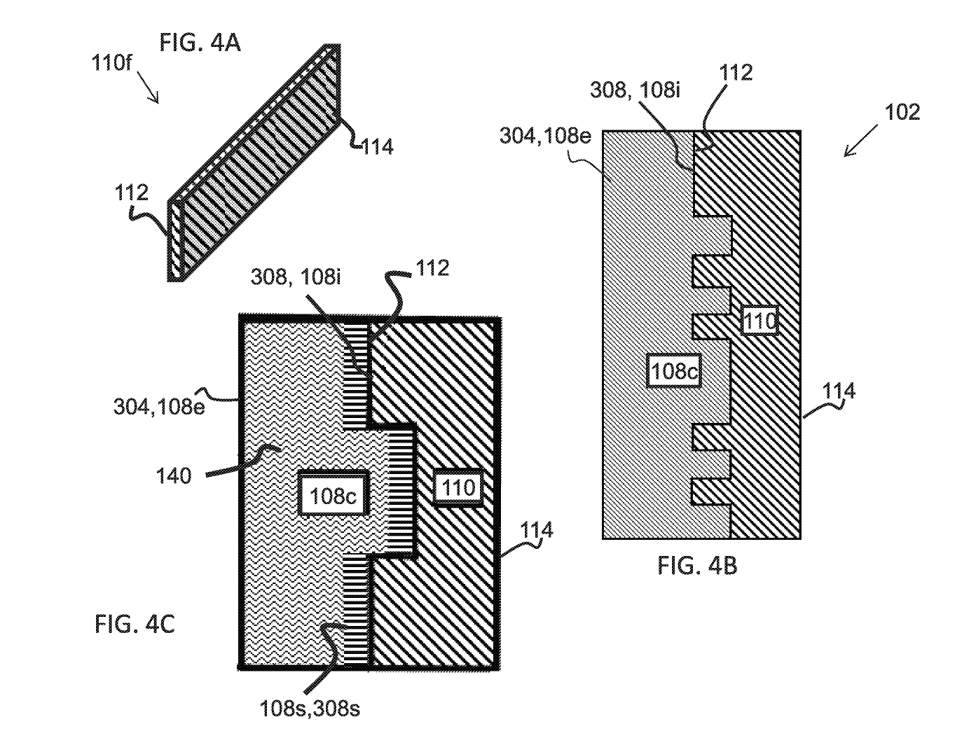

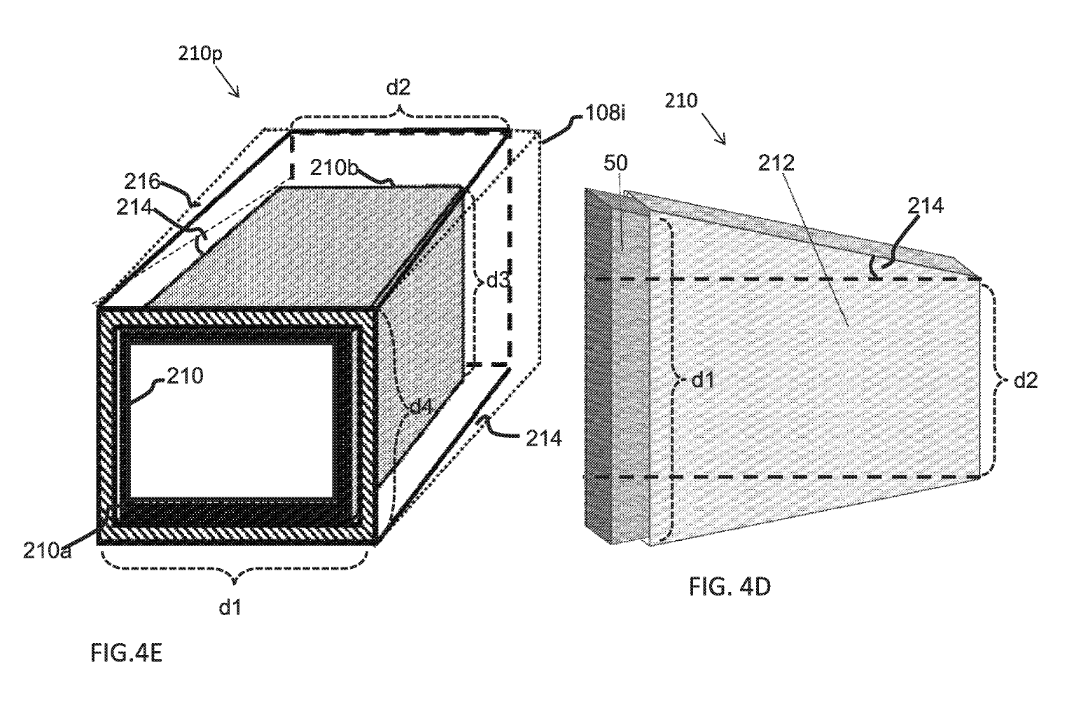

In embodiments, internal surface 108i is configurable on either of its dry side (associated with body 110) and/or wet side (associated with coolant 140) for example as shown in FIG. 4C. For example, the wet side of internal surface 108i may be provided with a high surface area configuration 108s, for example fins as shown, so as to improve heat conduction and heat exchange with coolant 140. The dry side of internal surface 108i may be provided increased surface area by utilizing an interlacing configuration, for example as shown in FIG. 4B.

Body 110 is provided in the form of a moveable body disposed internal to chamber 102, and capable of sliding and/or telescopically moveable along the full length of chamber 102 via open face 109.

Accordingly, body 110, generating direct or indirect heat, provides for mediating a heat conduction sequence and/or pathway from body 110 to a portion of internal surface 108i, 308 and onto the coolant 140, for example as shown with the white arrows in FIG. 1A.

In embodiments body 110 may be configured so as to snuggly fit within chamber 102, wherein both its shape and/or dimensions are configured according to the shape of chamber 102 such that body 110 will be receivable and telescopically movable along the length of chamber 102. Optional configurations of body 110 are described with respect to FIG. 4A-E.

Device 100 is characterized in that the thermal properties of device 100 are controllable and/or configurable for an intended application. For example, the cooling volume 108c may be customized to determine the temperature control properties of device 100 and in particular the static temperature control and/or cooling capacity of device 100. For example the cooling volume 108c may be configured so as to be proportional to the heat generated directly or indirectly by body 110 that is associated with device 100.

The temperature control properties of device 100 are provided by the combination of using a configurable e cooling volume 108c, as previously described as well as using materials having high heat conduction properties. Most preferably at least one of body 110 and/or internal volume 108i and/or heat exchanging surface 308 are provided from materials configured for efficient heat conduction so as to efficiently convey heat generated within chamber 102 to coolant 140.

In embodiments the heat exchanging surfaces selected from internal surface 108i, heat exchange surface 308, body 110 may comprise and/or incorporate high heat conducting materials for example including but not limited to at least one or more materials selected from: a metal, a metallic alloy, aluminum, an aluminum alloy, copper, a copper alloy, silver, silver alloy, gold, gold alloy, platinum, platinum alloy, nickel, nickel alloy, titanium alloy, titanium alloy, graphene, a polymer, polymeric alloys, shape memory materials, shape memory polymers, shape memory metallic alloys, electroactive polymers, magnetostrictive materials, photosensitive materials, materials sensitive to magnetic field, materials sensitive to an electric field, materials sensitive to electromagnetic radiation, materials sensitive to light, material sensitive to specific wavelength, or any combination thereof.

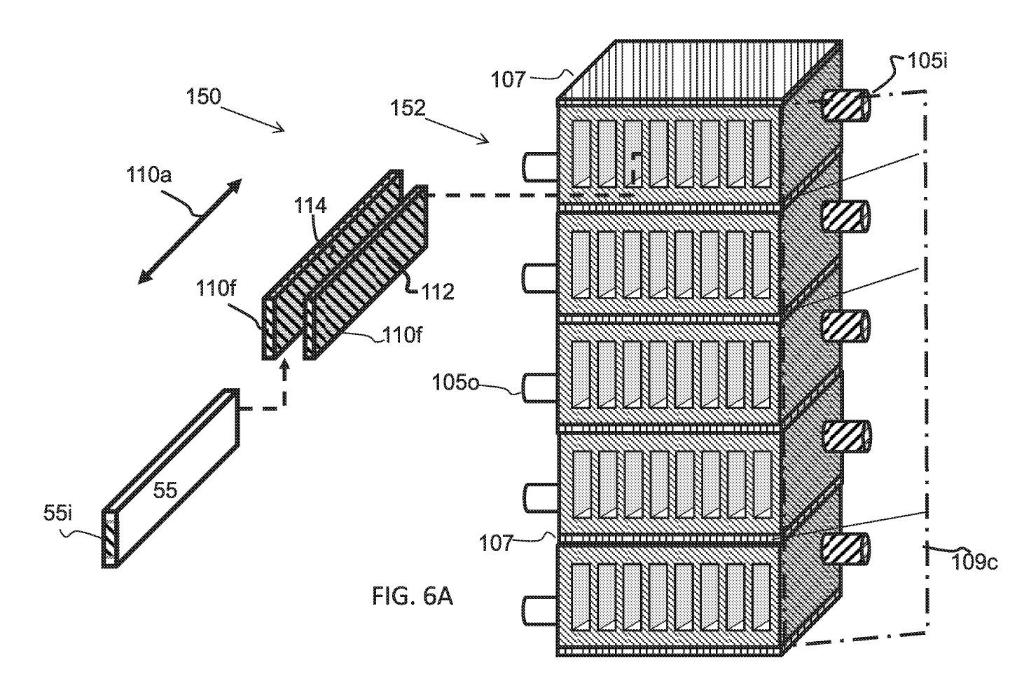

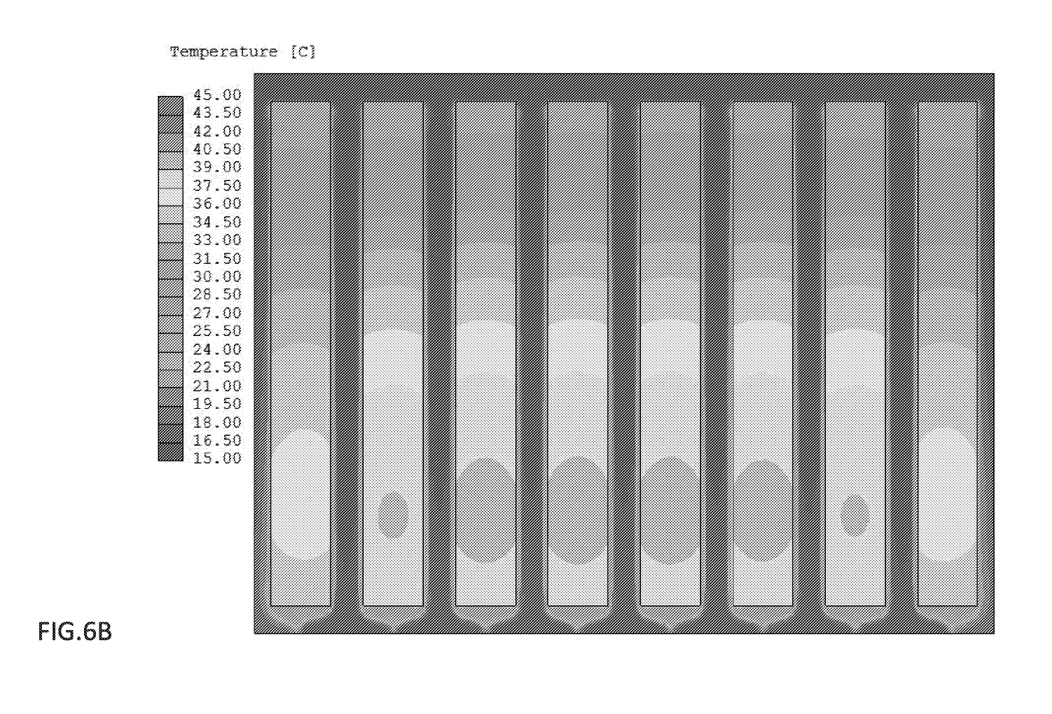

In embodiments, the external surface 108e may be further fit with an insulating layer 107, shown in FIG. 6A, so as to maintain optimal temperature range of coolant 140.

In embodiments, housing 108 may be further fit with at least one or more sensor and/or a sensor module for example in the form of a temperature sensor. Optionally a sensor module may be in communication with a processor and/or processing module to monitor and/or analyze the data provided from the sensors and for taking any action in response to the sensor data. For example, a temperature sensor may provide for actively and continuously monitoring the temperature fluctuations of different portions of housing 108.

In embodiments the surface area of internal volume 102 may be configured so as to maximize and/or promote heat exchange between internal volume 102 and internal surface 108i. Therein the shape and surface area of 108i may be configured so as to maximize the surface area to promote heat transfer to coolant 140 and therein provide a cooling effect within internal volume 102. Optionally such surface configuration may be provided by integrating smart materials within at least one surface of device 100.

In embodiments, internal surface 108i is configurable on either of its dry side (associated with body 110) and/or wet side (associated with coolant 140) for example as shown in FIG. 4C. For example, the wet side of internal surface 108i may be provided with a high surface area configuration 108s, for example fins as shown, so as to improve heat conduction and heat exchange with coolant 140. The dry side of internal surface 108i may be provided increased surface area by utilizing an interlacing configuration, for example as shown in FIG. 4B.

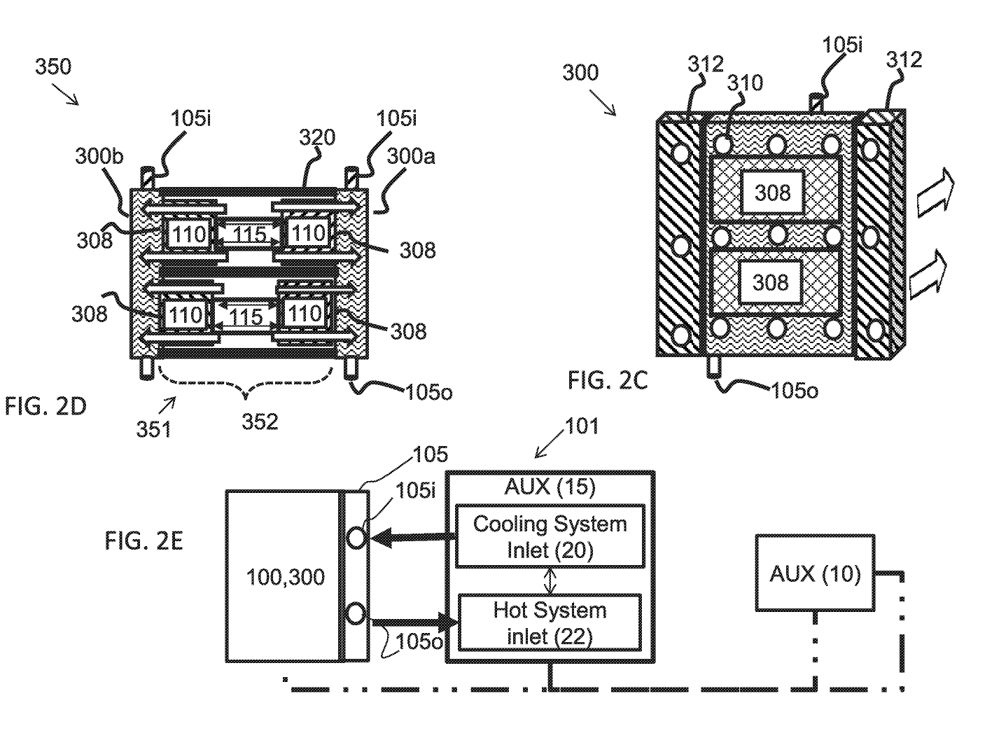

Circulating interface 105 provides for coupling device 100 with an auxiliary device or cooling system 15 provided for facilitating the flow of coolant 140 within cooling volume 108c, as shown in FIG. 2E. Auxiliary cooling device and/or system 15 may for example include but is not limited to a pump, a cooling system, liquid circulating device, the like or any combination thereof. Preferably cooling system 15 provides for controlling the temperature of coolant 140.

In embodiments, body 110 and/or intern surface 108i may be provided with a coating and/or layer to facilitate heat transfer and/or movement of body 110.

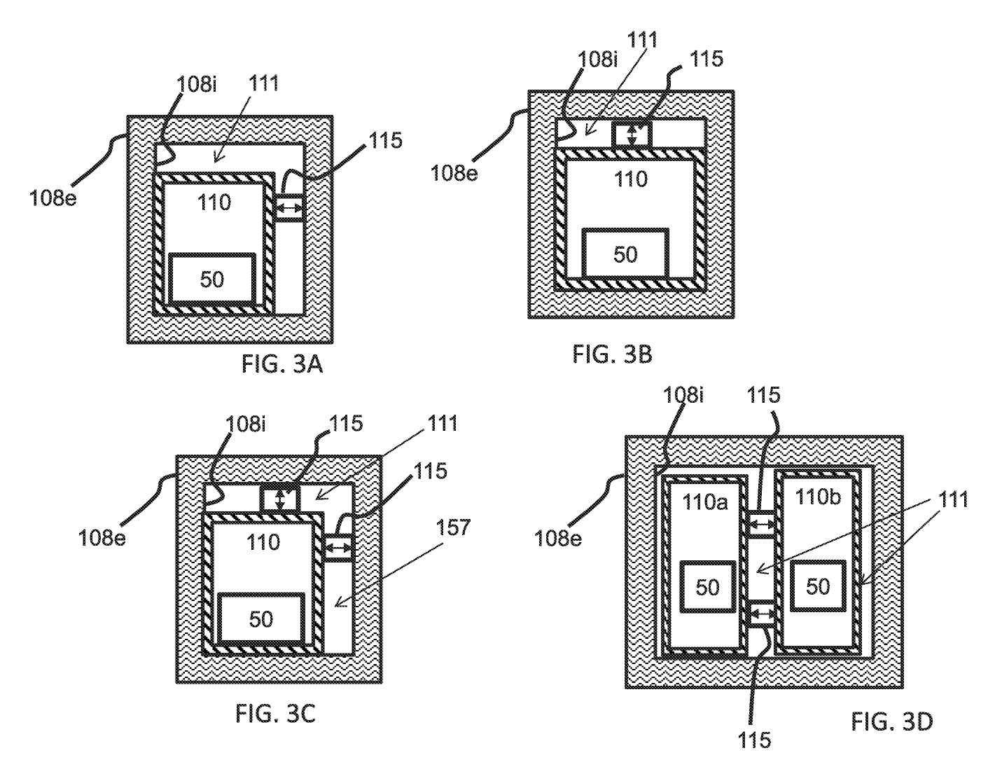

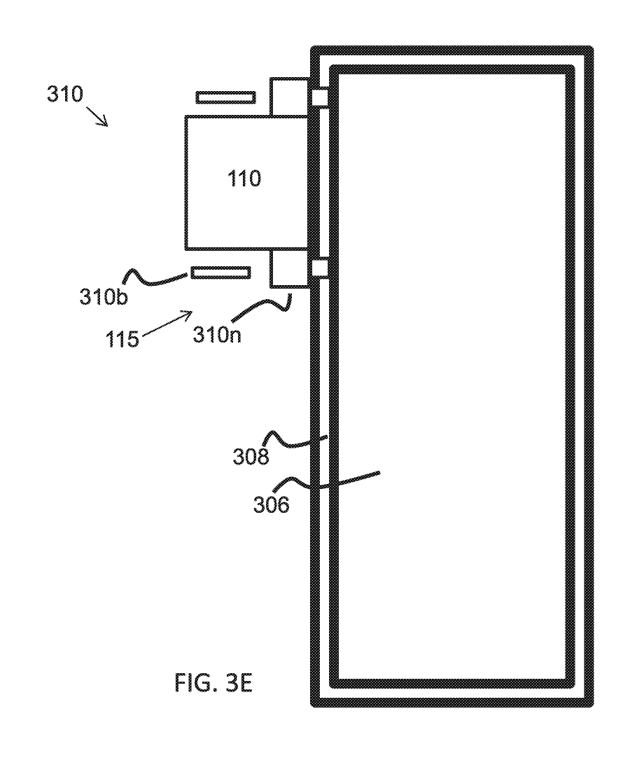

In embodiments, body 110 may be further fit with and/or associated with a positioning control module 115, for example as shown in FIG. 1A. Position control module 115 provides for controlling the position of body 110 within the internal volume 102, as shown in greater details in FIG. 3A-D. Preferably module 115 provided to improve heat conduction between body 110 and internal surface 108i and/or heat exchange surface 308.

Positioning control module 115 may be configured to urge moveable body 110 and/or a heat generating load 50 against a portion of internal surface 108i and/or heat exchange surface 308 so as to form close proximity thereto to improve heat transfer between the surfaces, as is discussed in greater detail with respect to FIG. 3A-D.

FIG. 2A-C show an embodiment of the present invention for a temperature control device and/or cooling device 300, that is similar to device 100 depicted in FIG. 1A-B. Device 100 is of FIG. 1A-B shows a cabinet-like configuration of a temperature controlling device according to embodiments of the present invention, while device 300 shown in FIG. 2A-C is provided with a planar “wall-like” configuration. In embodiments, the wall-like configuration may be used alone or in an assembly comprising two or more wall configurations, as will be show in in FIG. 2D.

FIG. 2A shows a face on view of device 300 providing a temperature control and/or cooling device, that is configured to maintain a body 110 associated therewith within a controllable temperature range and providing efficient static cooling.

Device 300 comprises an enclosed housing 302 having a closed surface 304 defining an enclosed continuous cooling volume 306 provided for housing a coolant 140. Coolant 140 flows within the cooling volume 306 with the aid of a coolant circulating interface 105 featuring an inlet 105i and an outlet 105o, as previously described with respect to device 100.

Housing 302 is shown having a rectangular geometric configuration however housing 302 is not limited to such a configuration and may be in any geometric shape.

Housing 302 has a planar configuration having at least one temperature controlling face featuring a heat exchange surface 308 that is configured to receive and/or associate with a body 110. Optionally housing 302 may be configured to have two planar temperature controlling faces disposed on opposing sides of housing 302 each face featuring a heat exchanging surface 308 configured to receive and/or associate with a body 110.

Most preferably at least a portion of surface 304 is provided from a high heat conducting material to define a heat exchanging surface 308 along a the planar face forming surface 304. Heat exchanging surface 308 is provided to receive and/or associate with a body 110 so as to allow for efficient heat exchange between surface 308 and a surface of body 110. Most preferably surface 340 is provided with a coupling interface module 310 provided for coupling and/or associating a body 110 onto surface 304 and more preferably heat exchanging surface 308. As described with device 100, device 300 may be configured to provide a configurable heat capacity and more preferably static cooling capacity by at least controlling the cooling volume 306 of housing 302, the cooling volume 306 preferably determines the static cooling capacity of device 300.

In embodiments the surface area of surface 304 and/or heat exchange surface 308 may be configured so as to maximize and/or promote heat exchange with coolant 140 and/or body 110. Therein the shape and surface area of surface 304 may be configured so as to maximize the surface area to promote heat transfer to coolant 140 and therein provide a cooling effect along surface 304 and/or 308. In embodiments, surface 304 and/or portion of surface 304 and/or heat exchange surface 308 may be configured to with a high surface area configuration along either or both of its dry side (associated with body 110) and/or wet side (associated with coolant 140 within cooling volume 306) for example as shown in FIG. 4C. For example, the wet side of surface 308 and/or 304 may be provided with a high surface area configuration 108s, for example fins as shown, so as to improve heat conduction and heat exchange with coolant 140.

Coupling interface module 310 may for example be provided in the form of a nut 310n and bolt 310b coupling assembly capable of coupling with a portion of body 110, as shown in FIG. 3E. Similarly nut and bolt assembly of FIG. 3E may similarly be utilized as form of a positioning control module 115. Optionally coupling module 310 may be provided in the form of a male/female couplers.

In embodiments, coupling interface 310 may be further fit with a position control module 115 provided for controlling the proximity and/or the pressure applied between body 110 and the heat exchanging surface 308 for improving heat conduction therebetween.

In embodiments coupling interface 310, 312 may be provided along the planar face of housing 302 along surface 304. In embodiments an optional coupling interface 312 may be provided in the form of a construct coupling interface 312. Construct coupling interface 312 provides for facilitating interlinking and/or coupling a plurality of housing 302, as shown in FIG. 2D. In embodiments, construct coupling interface 312 may be used to couple device 300 to a framework and/or construct so as to hold or give housing 302 structural support. Construct coupling interface 312 may therefore be utilized to couple device 300 to auxiliary constructs 320 and/or devices for example including but not limited to: a shelf, a wall, a support beam, a supporting structure, a support member, a framework, additional cooling devices 300, an automated storage and retrieval system (not shown), any combination thereof or the like.

FIG. 2B shows a side view of housing 302 where a side face is shown, and wherein the flowing inlet 105i and outlet 105o are disposed on opposing upper and lower surfaces, as shown.

FIG. 2C shows a further optional configuration of device 300 showing both construct coupling interface 312 disposed along edge or side surface of housing 302 and coupling interface 310 that is disposed adjacent to heat exchanging surface 308 along surface 304.

FIG. 2C further shows the directional arrow depicting the direction of heat conduction form heat exchange surface 308 into cooling volume 306 so as to utilize the heat capacity of coolant 140 disposed therein.

FIG. 2D shows a side view of an exemplary construct 350 that is formed from a plurality of devices 300 to form an optional cooling device assembly according to embodiments of the present invention.

As shown construct 350 comprises at least two individual devices 300 including a first device 300a and a second device 300b that are interconnected with one another utilizing construct coupling interface 312 with an optional construct 320 shown in the form of a shelf.

As can be seen each device 300a, 300b has an individual coolant flowing interface 105i, 105o.

Construct 350 comprising two oppositely facing devices 300a, 300b, that are coupled over a distance 352. Each device is oriented such that its individual heat exchanging surfaces 308 are facing one another across distance 352 forming an open side face 351 for accessing the length of surface 304 and/or 308. Each heat exchanging surface 308 is associated with at least one or more body 110. At least two or more bodies 110 may be disposed opposite one another forming at least a pair of oppositely facing bodies. More preferably each pair of oppositely facing bodies 110 are associated with a common and/or central positioning module 115 that is provided to urge each of body 100 toward its respective heat exchanging surface 308. For example, central positioning module 115 may be provided as an expandable balloon that urges body 110 onto surface 308 to optimize heat exchange between the two surfaces, similarly described in FIG. 3D below.

In embodiments, a construct 350 may utilize a body 110 that is configured to be moveable along the heat exchanging surface 308 and/or surface 304 along an axis that is orthogonal to the axis formed by distance 352. The movement of body 110 is provided so as to allow access to surface 308 and/or 304 along from open face 351.

In embodiments, a plurality of device 300 may be used to form a construct that forms a cabinet like configuration, similar to device 100, therein forming an internal volume for receiving a body 110, for example similar to chamber 102, so as to provide body 110 with at least one or more heat exchange surface 308 which may be utilized to cool and body 110 by a heat conduction sequence and/or pathway.

FIG. 2E shows a cooling system 101, according to embodiments of the present invention, comprising at least one device 100, 300 as described above that is in fluid communication with an auxiliary coolant flow system 15 provided for flowing and cooling a coolant 140 and/or maintaining coolant 140 at a preset temperature or within a preset temperature range via coolant interface 105.

Optionally auxiliary coolant flow system 15 may be realized as a liquid flow and cooling system as is known in the art comprising a cooling system inlet subsystem 20 that is connected to device 100, 300 via inlet 105i utilized to introduce and/or deliver coolant 140 in its cold state. System 101 further comprises an outlet subsystem 22 coupled with device 100 over outlet 105o provided for receiving “hot” and/or “used” coolant 140 after it has flown within and cooled device 100, 300. Optionally outlet subsystem 22 may provide for treating and/or re-cooling coolant 140 back to its initial state so that it may be readily reintroduced to device 100, 300 via inlet subsystem 20. Optionally sub-systems 20 and 22 may be interlinked to form a closed loop and/or seamless coolant cooling system 15.

Optionally inlet sub-system 20 may be independent of outflow sub-system 22 wherein each provides a secondary use. For example, inlet system 20 may be a continuous fluid source while outlet system 22 may be a secondary use system that utilized “hot” coolant for secondary uses.

Preferably cooling system 15 may be configured to determine the kinetic cooling capacity of system 101 and/or devices 100, 300. Optionally the kinetic cooling capacity may be configurable by controlling parameters associated with system 15 for example including but not limited to coolant flow rate, coolant temperature range, minimum temperature, maximum temperature, any combination thereof or the like.

In embodiments, device 100, 300 may be further linked and/or functionally associated with an optional auxiliary system 10 for example in the form of a control sub-system 10 that may provide for monitoring and/or controlling device 100, 300 independently or in conjunction with the coolant cooling system 15. For example auxiliary system 10 may provide for controlling the cooling system 15 to control coolant flow rate through system 15. For example, an auxiliary control and communication subsystem 10 may be utilized to continuously monitor the temperature levels of device 100, 300 so as to ensure its proper operation and to communication and/or sound an alarm and/or take any necessary action to ensure its continuous operation. Control sub-system may for example be provided in the form of a communication and processing device such as a computer, mobile computer, mobile processing device, the like or any combination thereof. Control sub-system 10 may be in wireless communication with at least one or more members of system 101. Control sub-system 10 may further comprise a display and/or graphical depiction of the performance of device 100, 300 and/or systems 101.

In embodiment sub-system 10 may be provided for controlling and/or communicating at least one or more position control modules 115 associated with device 100, 300 to facilitate operational control of device 100, 300 and/or system 101 and in particular to manage temperature fluctuations and/or performance.

In embodiments sub-system 10 may further comprise a sensor and analysis module for sensing the temperature fluctuations of device 100, 300.

In embodiment sub-system 10 may be provided for monitoring and/or communicating with at least one or more sensors that may be disposed and/or associated with device 100, 300 or system 101. For example, a sensor module that may be associated along a portion device housing 108, 302 so as to facilitate monitoring operations for example providing for continuously sensing temperature of at least a portion of device 100, 300 or system 101.

In embodiment sub-system 10 may be provided for wired and/or wireless communication with at least one or more devices for example including but not limited to device 100, 300, system 101, coolant cooling system 15, or additional auxiliary devices.

FIG. 3A-3D show a schematic illustration of an optional form of a positioning module 115 shown in the form of an actuator that provides for approximating moveable body 110 to internal surface 108i or heat exchange surface 308 and/or surface 304 so as to minimize a gap and/or space 111 formed between body 110 and at least one of surface 304, heat exchange surface 308, and/or internal surface 108i. Preferably reducing and/or controlling the size of gap 111 provides for placing moveable body 110 as close as possible to surface 108i, 308, 304 and therefore to coolant 140 so as to improve heat transfer between the surfaces.

Optionally positioning module 115 may provide for controlling the pressure applied between at least one surface of body 110 and at least a portion of a surface 108i, an/or heat exchange surface 308, so as to facilitate thermal conduction and heat exchange between the two surfaces.

In embodiments, position control module 115 may be disposed on either one or both of the body 110 and/or the internal surface 108i and/or heat exchange surface 308 and/or surface 304, for improving heat conduction therebetween.

FIG. 3A shows a schematic configuration wherein an optional positioning module 115 is provided to urge body 110, by way of motion toward the left side, toward a side surface of internal surface 108i, therein facilitating heat exchange between the surfaces.

FIG. 3B shows a schematic configuration of device 100 wherein an optional positioning module 115 is provided for urging a lower surface of body 110, by way of downward motion, so as to allow the approximation of lower surface of moveable body 110 toward a lower surface of internal surface 108i.

FIG. 3C shows a further schematic configuration wherein two or more positioning modules 115 are utilized to urge two surfaces of moveable body 110 toward two surfaces of internal surface 108i. As shown, a first positioning module 115 provide for downward motion urging moveable body 110 downward; and a second positioning module 115 provides for sideway motion (left) toward a side surface of internal surface 108i.

FIG. 3D provides an additional schematic illustration of an optional positioning module 115 provided in the form of at least one or more inflatable balloon and/or volume so as to urges at least one or more heat generating load 50 and/or moveable body 110 from a central position against at least one or more side surface 108i so as to increase heat exchange therebetween.

In embodiments positioning module 115 may be provided in optional forms for example including but not limited to and/or comprising at least one or more selected from: an actuator, a linear actuator, a piezoelectric actuator, a remotely controllable actuator that may be controlled with a remote wireless control signal, a coupling assembly comprising male and female couplers, a coupling assembly comprising a nut and bolt assembly, a magnetic coupling assembly, an inflatable balloon assembly, a remotely controllable inflatable balloon assembly wherein the volume of the inflatable balloon is controllable with a remote wireless control signal, any combination thereof or the like.

In embodiments positioning control module 115 may be monitored and/or controlled with a remote monitoring system, for example a dedicated auxiliary sub-system 10 by way of wired and/or wireless communication.

Now referring to FIG. 4A-E showing various configurations for a body 110 construct according to embodiments of the present invention.

Body 110 shown removed from internal volume 102 and device 100, may be configured to have any two dimensional or three dimensional geometric shape for example including but not limited to rounded, polygonal of n sides wherein n is at least 3 (n≥3), ovoid, elliptical, cylindrical, circular, tubular, conical, trapezoidal, hexagonal, the like or any geometric configuration that allows for interfacing with a heat conducting surface 308 and/or internal surface 108i and/or to be receivable within inner volume 102.

Body 110 may be provided from and/or comprise optional materials that are good heat conductors and more preferably having high heat conducting properties to facilitate mediating heat conduction toward coolant 140. Accordingly body 110 may utilize and/or incorporate high heat conducting material for example including but not limited to at least one or more materials selected from: a metal, a metallic alloy, aluminum, an aluminum alloy, copper, a copper alloy, silver, silver alloy, gold, gold alloy, platinum, platinum alloy, nickel, nickel alloy, titanium alloy, titanium alloy, graphene, a polymer, polymeric alloys, shape memory materials, shape memory polymers, shape memory metallic alloys, electroactive polymers, magnetostrictive materials, photosensitive materials, materials sensitive to magnetic field, materials sensitive to an electric field, materials sensitive to electromagnetic radiation, materials sensitive to light, material sensitive to specific wavelength, or any combination thereof.

FIG. 4A shows a body 110 having a two dimensional rectangular planar configuration 110f having a first face 112 for associating with a heat exchange surface 308 or an internal surface 108i of volume 102 and a second face 114 for associating with a heat generating load 50.

FIG. 4B-C shows optional surface configurations and interaction between body 110 and heat conduction surface 308 and/or internal surface 108i. Preferably the interaction between body 110 and the heat conducting surface 308 and/or internal surface 108i is configured to promote heat exchange therebetween so as to convey any heat toward coolant 140. Preferably the surface interaction may be configured according to the materials used and/or the geometric configuration of surfaces 110, 308, 108i. For example a high surface area configuration between first face 112 of body 110 and surface 308, 108i so as to promote heat conduction between them. FIG. 4B-C shows a high surface area configuration between surfaces 110 and 308 and/or 108i, in the form of an interlacing and/or corresponding surface having corresponding male and female configuration. Optionally any such interlacing may be utilized for example a sinusoidal wave configuration. Optionally such interlacing may provide a track and rail configuration to facilitate movement of body 110 along a heat exchanging surface 308 and/or internal surface 108i.

In embodiments, internal surface 108i is configurable on either of its dry side (associated with body 110) and/or wet side (associated with coolant 140) for example as shown in FIG. 4C. For example, the wet side of internal surface 108i may be provided with a high surface area configuration 108s, for example fins as shown, so as to improve heat conduction and heat exchange with coolant 140. The dry side of internal surface 108i may be provided increased surface area by utilizing an interlacing configuration, for example as shown in FIG. 4B.

FIG. 4D-E shows two optional three dimensional configurations of body 110 having a trapezoidal configuration provided for fitting within a lengthwise inner volume chamber 102 that may be formed with device 100 and/or a construct utilizing a plurality of devices 300, as previously described.

FIG. 4D shows a body 110 configured to fit within volume 102 with a trapezoidal configuration 210. Trapezoidal body 210 having at least four surfaces forming a trapezoidal box configuration capable of receiving a heat generating body 50 within the four surface configuration, wherein at least two opposing non-parallel side walls 212 are provided at a first angle 214, and wherein the side walls 212 are configured to be heat conducting surfaces that are in contact with an internal surface 108i or surface 308, to facilitate heat conduction and to generate pressure along at least a portion of the side walls 212. More preferably first angle (214) is defined between a front face 210a having a first dimension d1 and a back face 210b having a second dimension d2 configured such that d1>d2.

FIG. 4E shows a further optional trapezoidal configuration of a body 110, that is provided in the form of a trapezoidal prism body 210p. The trapezoidal prism body 210p comprises at least four opposing non-parallel side walls 212 wherein each pair of side walls are provided at a first angle 214 and a second angle 216. Preferably side walls 212 are configured to be heat conducting surfaces that are in contact with an internal surface 108i or surface 308, to facilitate heat conduction. The trapezoidal prism body configuration 210p has a first face 210a having dimensions (d1, d4) and a second face (210b) having dimensions (d2, d3) that are configured such that d1>d2, define a first angle 214, and d4>d3 define a second angle 216. More preferably side wall angles 214, 216 are provided to facilitate heat conduction so as to generate pressure along at least a portion of the side walls 212.

In embodiments body 210p may be provided with a face 210a, 210b having any polygonal configuration or shape for example including but not limited to quadrilateral, rectangular, rhomboid, square, the like or any combination thereof.

In embodiments body 210p may be provided with a face 210a, 210b having any circular and/or elliptic configuration forming a conic section, cylindrical tube-like segments, the like or any combination thereof.

In embodiments body 210p, 210 may be provided with a front face 210a and a back face 210b is configured such that at least one dimension of front face 210a is larger than the corresponding dimension of back face 210b.

In embodiments body 210p may be provided with a front face 210a and a back face 210b configured such that two dimension of front face 210a is larger than the corresponding dimension of back face 210b. Such a prism configuration for body 210p may be provided with any geometric configuration for example including but not limited to oval, ovoid, circular, polygonal, quadrilateral the like or any combination thereof.

In embodiments at least one of font face 210a or back face 210b of body 210, 210p are provided as an open face. More preferably first face 210a defining an open face for receiving a heat generating load 50 therethrough, for example in the form of electronic circuitry.

FIG. 5A-D show a front face on view schematic illustration of optional configuration of device 100 in the form of a data center rackmount 150, having a plurality of internal volumes 102, that may also be referred to as slots, arranged along a front open face 109 of rackmount assembly 150. The arrangement may be provided to provide optimal heat management of body 110 and/or any heat generating load 50 associated therewith, within individual internal volume 102. As seen, a coolant 140 is provided along all surfaces of a plurality of internal volumes 102 except for that of open face 109 which is utilized to gain access the contents of volume 102. Preferably face 109 further provides an interface access point for a body 110 alone or in combination with a heat generating load 50, for example in the form of a blade server or the like electronic circuitry, wherein communication and/or powering interfaces of the electronic circuitry may be oriented to face surface 109 so as to allow a user easy access to the power and/or communication interface as needed.

FIG. 5A shows an optional arrangement of device 100, wherein internal surface 108i is configured to form a plurality of inner volumes 102 each capable of receiving at least one or more body 110 and/or a heat generating load 50. Each inner volume 102 may be configured to receive at least one or more blade server or the like electronics within volume 102. Optionally such a blade server may be associated and/or integrated with a body 110 provided to interface with internal surface 108i so as to improve heat conduction between the two layers.

As previously described individual volume 102 may be further fit with a position control module 115. Such a position control module 115 may be disposed anywhere within volume 102, for example as depicted in FIG. 3A-D.

As shown in FIG. 5A, internal surface 108i of rackmount 150 is organized in a 5 layer rackmount configuration where each rackmount layer and/or slice 152 comprises 8 internal volumes 102 also referred to as slots. Each slot 102 is provided for receiving a body 110 and/or a heat generating load 50, for example a blade server as described above.

More preferably the dimension of each slot formed by open volume 102 is minimized so as to maximize heat control of the body disposed within volume 102 so as to maintain and/or limit the temperature of the body 110 associated therein within a controllable temperature range.

As shown, rackmount 150 is provided with an intel 105i and an outlet 105o that provide for enabling the flow of a coolant 140 therebetween. Preferably coolant flow between inlet 105i and outlet 105o is provided by an auxiliary coolant circulating system 15, for example as shown in FIG. 2E. Preferably an auxiliary system 15 in the form of a coolant circulating system accounts for the kinetic cooling capacity of rackmount 150, for example by controlling the coolant flow rate, while the static coolant volume disposed within cooling volume 108c defines the static cooling capacity of rackmount 150.

FIG. 5A-D further show optional configurations for individual internal volumes 102 as provided by optional configuration of internal surface 108i. As shown the shape of volume 102 may be configurable according to the application and may be polygonal and/or cylindrical, for example a shown in FIG. 5B.

Most preferably the shape and/or configuration of internal volume 102 and/or internal surface 108i is configured so as to determine the cooling volume 108c of rackmount 150 so as to control the static cooling capacity of rackmount 150. Preferably the rackmount cooling capacity and/or performance configuration may be determined based on at least one or more configurable parameters for example including but not limited to: the cooling volume 108c, the configuration of the internal surface 108i, the shape of the internal volume 102, the volume of the internal volume 102, at least one dimension of the internal volume 102, any combination thereof or the like.

Furthermore the overall heat capacity of device 100 shown in the form of a rackmount 150 is configurable according to at least one or more parameter for example including but not limited to: the functional temperature range requirement of a heat generating load associated within volume 102 and/or slot 108; the required static cooling capacity of rackmount 150, the required static cooling capacity of inner volume 102; the required minimal static cooling time (the time a body and/or heat generating load within volume 102 without circulation); required static cooling temperature range; the functional temperature range; minimum temperature; maximum temperature; coolant flow rate and/or circulation flow rate; the coolant type; non-circulation time frame; any combination thereof, or the like.

FIG. 6A-B shows an embodiment of device 100 according to the present invention, wherein an arrangement of cooling device 100 is realized in the form of a datacenter rackmount 150 capable of receiving a plurality of heat generating loads 50 in the form of blade servers 55 associated and/or integrated with a planar body 110f and fit within an individual volume 102 forming a data center slot. Each slot may be fit with a position control module 115, as previously described.

Rackmount 150 comprises five individual layers 152 each layer formed from an individual cooling devices 100 that are arranged in a stack formation forming rackmount 150. Each cooling device 100 or layer 152 comprises eight individual liquid free volume 102, also referred to as slots, each slot configured to receive and house at least one blade server 55. Accordingly rackmount 150 provides for housing at least 40 blade serves 55 or the like heat generating load 50.

Optionally and preferably each blade server 55 is disposed on a body 110f configured to fit within and be moveable within inner volume 102 to provide for gaining access to the full length of volume 102. The movement of body 110f along the length of slot 102 is shown with arrows 110a.

Each layer 152 is insulated with an insulating layer 107 along at least one surface. Insulating layer 107 may be provided along an upper surface and/or lower surface of device 100. Optionally device 100 may be fit with an insulating layer 107 along any of its surfaces formed by housing 108 more preferably along an external surface 108e as previously described.

In embodiments each slot 102 may be fit with a heat generating assembly comprising two planar bodies 110f that are coupled to a blade server 55 along a second face 114, in a sandwich-like configuration, wherein a single heat generating assembly is fit within slot 102. Most preferably such heat generating assembly is oriented such that the first face 112 of body 110f is in heat exchange contact with the heat exchange surface 308 of internal surface 108i forming slot 102.

In embodiments each slot 102 may be fit with two heat generating assembly each heat generating assembly comprising a planar body 110f that is associated with an individual blade server 55, along a second face 114, wherein a first face 112 of planar body 110f is in heat exchange contact with the heat exchange surface 308 of internal surface 108i forming slot 102. Both heat generating assemblies may be further associated with a positioning control module 115 configured to urge the first surface 112 of body 110f onto the heat exchange surface 308 of internal surface 108i forming slot 102, so as to improve heat exchange by increasing contact area between the surfaces and/or by increase pressure applied between the two surfaces.

In embodiment each planar body 110f may form a blade server and/or integrated therewith such that the heat generating load is provided in the form of body 110f. Optionally and preferably such an integrated heat generating body may be directly fit with a position control module 115.

Each layer 152 is provided with an individual coolant circulating interface 105, provided for circulating coolant 140 between inlet 105i, for introducing coolant 140 into cooling volume 108c of device 100, and an outlet 105o for conveying circulated “used” and/or “hot” coolant 140. Not shown is an auxiliary coolant circulating system 15, as previously described with respect to FIG. 2E, that is coupled to inlet 105i and outlet 105o. More preferably coolant 140 flows around all surfaces slot 102 therein providing a surrounding cooling effect that surrounds the content of slot 102 around the heat exchange surface 308 of internal surface 108i.

In embodiments inlet 105i and 105o may be provided along the same surface of device 100, for example as shown in FIG. 5A.

In embodiment inlet 105i and outlet 105o may be provided along a different surface of device 100, for example as shown in FIG. 6A.

In embodiments the location of inlet 105i and outlet 105o may be depicted so as to establish the optimal coolant flow and/or temperature control within device 100 so as to limit temperature fluctuation (range) of a load 50, 55 disposed therein to a predetermined level, for example 4 degrees Celsius.

Most preferably coolant 140 is provided in the form of water, or a water based solution for example including but not limited to: double distilled water, natural water, sea-water, fresh-water, recycled water, filtered water, any combination thereof or the like water based liquid or compound.

Most preferably housing 108 and in particular coolant volume 108c provides for housing a large volume of coolant 140, so as to allow for maintaining and/or limiting temperature fluctuation throughout device 100, body 110 and/or an associated heat generating load 50, 55 and further provides rackmount 150 with a configurable static heat capacity as previously described.

Preferably cooling volume 108c defines a coolant reservoir (or tank) that provides for allowing the storage and flow of a cooling-liquid 104 via coolant inlet 105i and outlet 105o. The liquid 140 can flow from inlet 105i disposed at and/or near an upper edge and flows across to outlet 105o disposed at and/or near a lower edge, on an opposite face of layer 100 for example as shown in FIG. 6A. Most preferably, outlet 105o is utilized for removing cooling-liquid and waste heat away from the rackmount 150. Optionally outlet 105o may be fit with valves so as to control the flow therethrough.

FIG. 6A shows a front face on view showing face 109 of rackmount 150 wherein face 109 provides the accessing and fitting volume 102 with heat generating load 50 shown in the form of a blade server 55. Blade 55 includes a communication and power interface 55i that provides for coupling blade 55 with additional processing units and/or electronic circuitry and/or communication units as is known in the art. Most preferably blade 55 is oriented within internal volume 102 and/or body 110f where interface 55i is facing front face 109 allowing a user access so as to couple and/or wire up blade 55, as is needed.

Optionally face 109 of rackmount 150 may further comprise at least one or more door and/or front cover 109c, as schematically shown, to close and/or cover front face 109. Cover 109c in the form of a door may be provided with a single door, as shown, for further insulating rackmount 150 to ensure temperature control. Optionally rackmount 150 may be fit with a plurality of doors, each associated with at least one or more individual layer 152 wherein each door is provided for further insulating an individual layer 152 of rackmount 150 to ensure temperature control thereof. Optionally cover 109c may be fit with insulating material along its edges and/or any surface thereof.

In embodiments, individual device 100 and/or layer is configured so as to allow individual slots/open volume 102 to transfer up to about 10 kW of heat generated by body 110f and/or a load 50, 55 associated therewith to coolant 140. In embodiments, device 100 and/or layer 152 may be configured to provide up to about 8 kW of heat absorption. Optionally device 100 and/or layer 152 may be configured to provide up to about 5 kW of heat absorption.

In embodiments, as shown in FIG. 6A-B each slot and/or open volume 102 may be provided with dimension of about 546 mm (height)×750 mm (length)×90 mm (width) and is configured to be surrounded in coolant 140.

In embodiments, the cooling volume 108c of device 100 and/or individual layers 152 forming rackmount 150 may comprise a coolant 140 having a volume capable of holding up to about 1000 liters of coolant, more preferably from at least about 50 liters and up to about 500 liters. In embodiments device 100 may be provided with a coolant volume of about 50 liters, 60 liters, 70 liters, 80 liters, 90 liters, 100 liter, 150 liter, 200 liters, 250 liters, 300 liters, 350 liters, 400 liters, or about 500 liters.

Device 100 that is provided with a large volume of coolant 140 is therefore configured to have a high thermal capacity such that it can maintain operational temperature levels even when the coolant circulating system 15 is devoid of power. Accordingly device 100 may be configured to run without the need for a Uninterrupted Power Supply (UPS) system as needed for critical systems. The high heat capacity provided by device 100, particularly the static (non-flowing) heat capacity as previously described, allows rackmount 150 to run without a critical system back up in the form of a Uninterrupted Power Supply (UPS) as it is sufficient to operate rackmount 150 and/or device 100 without a UPS. Accordingly the high static heat capacity offered by the rackmount 150 and devices 100, 200 according to embodiments of the present invention renders a UPS superfluous, which translates into savings and operational costs reduction as the rackmount 150 and/or device 100 does not need to be defined as a critical system.

As assembly of the rackmount 150 shown in FIG. 6A is capable of maintaining operational temperature for up to 4 minutes of downtime of cooling system 15 in the form of a coolant circulating system. Device 100 allows for configuring device 100 and/or rackmount 150 with such a long downtime due to the large cooling volume 108c, 306 for housing a large volume of coolant 140 that continuously surrounds the contents of slot and/or volume 102.

This is true even when the coolant is not actively circulated, as the coolant has high heat capacity and may continue to absorb heat produced by heat generating loads disposed in rackmount 150, for example by load 50, 55. Therefore device 100 according to embodiments of the present invention eliminates the need for UPS power backed-up cooling system.

In embodiments, the volume of coolant 140, in the form of water, disposed in cooling volume 108c, 306 provides device 100, 300 with a static cooling capacity of about 1 kcalory/° C. per liter of coolant 140. Accordingly the cooling volume 108c, 306 of device 100, 300 may therefore be configured to provide a rackmount 150 with a designated and/or controllable cooling capacity according to the heat generating load used with the device 100, 300 and/or assembly 150, 350.

To provide enough heat transfer properties between the body 110 and/or load 50 with heat conducting surface 308 of internal volume 102 the rackmount 150 may be designed with the following parameters used in the formula:

W=K*A*(T1−T2)/d [equation 1]

W in watts, is the total heat energy transferred from the internal contents of volume 102 to the coolant 140 per second;

K is the thermal conductivity between the body 110 and the heat conducting surface 308 and/or internal surface 108i;

A is the area allotted for heat transfer, assuming heat transfer only occurs along a portion of \body 110, for example first face 112, assuming dimensions of about 10 cm×50 cm=500 cm²=0.05 m²;

ΔT=T2−T1 is the preset temperature differential capacity, assumed to be equal to up to 10° C., wherein T1 is the higher temperature and T2 is the lower temperature;

d is the distance along which the heat transfer takes place, therefore it is the thickness of first face 112 of body 110, as it is assumed that that is the only surface where active heat transfer occurs, assuming the surface has a thickness of about =0.1 mm=0.0001 m;

Therefore, the content of each open volume 102, including body 110 any heat generating load 50 associated or integrated therewith, can generate up to 10 kW of heat energy and the temperature of the body 110f will rise up by 10° C. over the base temperature (T2) of the coolant 140.

Assuming that the entire surface of first surface 112 of body 110f is in heat transfer contact with the heat conducting surface 308 of each open volume 102 utilized in rackmount 150 that would result results in a heat transfer capacity of up to 40 kW within each slot 102 of rackmount 150. This configuration allots for a temperature rise of the heat generating load to rise by no more than 10° C. which is absorbed by coolant 140.

Accordingly, in embodiments a device 100 comprising a racking arrangement including 20 slots and/or inner volumes 102, is configured to absorb about 200 kW even under the assumption that only the bottom surface of moveable body 100 transfers all the heat generated by load 50.

Furthermore, if more surfaces of the moveable body 100 surfaces are actively involved in the heat transfer, device 100 may multiply the amount of heat transfer by the amount of surfaces involved. Accordingly if all surfaces of a body 110 having four heat conduction surfaces are provided as active heat transferring bodies device 100 can be configured so that a rackmount having 20 open volume 102 can absorb to about 800 kW of generated heat.

In another example, a cabinet racking arrangement similar to that shown in FIG. 6A can contain more than 300 liters of cooling-liquid. In the case of water, each liter can absorb 1 kCalories/° C. Therefore to heat 300 liters by 1° C. requires 300 kCalories and to heat 300 Liters by 10° C. requires 3000 kcalories. 3000 kCalories absorb 12560400 Watt*sec (1 kCalorie=4186.8 W*s). Thus, 12560400 W*s is equal to 104670*120 seconds, therefore providing 2 minutes of static cooling capacity. Therefore a rackmount configuration having 300 L of cooling volume 306, 108c that is filled with a coolant 140 in the form of water can provide at least 2 minutes of static cooling capacity solely due to the cooling volume of device 100, 300 so as to absorb a 10 degree Celsius by coolant 140 in the form of water.

In conclusion, a cabinet racking arrangement configured to absorb 100 kWatt for a period of 2 minutes, wherein the coolant temperature, in the form of water, temperature will increase by 10° C. Therefore, the chamber heat capacity may be given by the below equation:

Q=CP*L*ΔT [equation 2]
Q—is the Heat capacity of the chamber (Watt*second);
CP is the specific heat capacity of coolant (J/g° C.);
L—volume of coolant in device Amount of liquid in the chamber in liters;
ΔT=T2−T1=10° C., temperature differential;
T1—The higher temperature of the chamber
T2—The lower temperature of the chamber;
Accordingly, the time that the chamber can operates in static cooling conditions where the liquid coolant is not flowing is given by the following:

t=Q/P [equation 3]
P is the power that all the heat generating bodies radiates in volume 102;

Accordingly, for a racking arrangement with 300 liters of coolant 140 in the form of water and a preset level of temperature differential of ΔT=10° C. the maximum time of operating during static cooling conditions without flowing coolant is given as a function of the heat generated by the body and/or load, for example in the form of a blade server, is given by Table A below, as:

TABLE A

| | T (sec) static cooling time frame for |
|---|---|
| P (Kw) heat generated by load | 10° C. temperature rise |
| 50 | 251 |
| 100 | 125 |
| 200 | 62 |
| 400 | 31 |

Conventionally, a 60 second latency period is considered to be sufficient time to initiate, non-critical system measures (UPS) such as a activating a generator for generating backup electricity for any data center. Therefore the auxiliary cooling system (15) associated with device 100, 300 does not require a specific UPS or the like critical system backup measures as it may use the standard system backup measures including a generator. Accordingly the need for a cooling system specific UPS and/or battery or the like critical system backup measures is not necessary with the device and system according to embodiment of the present invention.

FIG. 6B shows experimental results with modeling of a data center rackmount 150 shown in FIG. 6A, and shows results of a single layer 152 encompassing a device 100 having 8 slots and/or inner volumes 102 that are surrounded by a coolant 140 in the form of water, as previously described. The experiment modeled a rackmount arrangement as shown in FIG. 6A wherein each slot/inner volume 102 is fit with a heat generating load 50, 55 that is configured to produce about 4 kW of heat energy. Accordingly, the rackmount 150 of FIG. 6A is tested to produce a total of 160 kW of heat.

Each inner volume cell 102 was provided with the following dimension, 546 mm; cell 102 and surrounded by internal surface 108i having a thickness of about 30 mm, and it is surrounded by a coolant volume 108c having a thickness of about 12.7 mm. Accordingly the total height of each layer 152 is about 630 mm and the overall rackmount height 150 is about 3150 mm.

Accordingly applying equation 2 above given, the overall heat generated by the mounted loads is about 161 kW, a preset coolant (140) flow rate of 0.0096 m³/s results in a controllable temperature differential (ΔT) that utilizing these parameters rackmount 150 limits the temperature fluctuation to be at most 4° C., with the coolant temperature at inlet 105i is set to 15° C.

FIG. 6B shows that the temperature distribution along device 100 and inside the slots 102, showing that a rackmount 150 with the parameters discussed above efficiently cooled where the internal temperature of the inner volume 102 does not exceed 39° C. at its hottest location, found in the middle cells, while the majority of the slots are kept well below temperature level of 37° C.

In embodiments with the utilization and integration of smart materials within slot 102 as discussed above the temperature may be further controlled as the temperature changes overtime. For example, smart materials may be incorporated within the central slots experiencing the highest, though acceptable, heat generation, such that as the temperature increases beyond a threshold value a slight change in the smart material configuration, for example to assume a higher surface area configuration, would result in the necessary temperature reduction.

In embodiments the temperature distribution may be further controlled and/or regulated by employing at least one or more position control module 115, as previously described. For example, in response to a temperature increase a position control module 115 may be employed automatically and/or remotely to increase the surface pressure applied within the hottest slots, central slots as shown in FIG. 6B. The increase surface pressure applied locally within the central slots would reduce the temperature by promoting more heat exchange locally at the location where pressure is applied by control module 115.

While the invention has been described with respect to a limited number of embodiment, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

Therefore, the foregoing is considered as illustrative only of the principles of the invention. Further, since numerous modifications and changes will readily occur to those skilled in the art, it is not described to limit the invention to the exact construction and operation shown and described and accordingly, all suitable modifications and equivalents may be resorted to, falling within the scope of the invention.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable sub-combination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the scope of the appended claims.

Citation or identification of any reference in this application shall not be construed as an admission that such reference is available as prior art to the invention.

Section headings are used herein to ease understanding of the specification and should not be construed as necessarily limiting.

While the invention has been described with respect to a limited number of embodiments, it will be appreciated that many variations, modifications and other applications of the invention may be made.

1. A cooling device (300) comprising:
a. an enclosed housing (302) having a surface (304) defining an enclosed continuous cooling volume (306); wherein a high heat capacity liquid phase coolant (140) flows within said cooling volume (306) with a coolant circulating interface (105) featuring an inlet (105i) and an outlet (105o);
b. wherein at least a portion of said surface (304) comprises a high heat conducting material defining a heat exchanging surface (308);
c. wherein said housing comprises a coupling interface module (310) for coupling a body (110) onto said heat exchanging surface (308) for cooling said body (110) by a heat conduction sequence from said body (110) to said coolant (140);
d. wherein heat generated directly or indirectly by said body (110) is conducted toward said heat exchanging surface (308) and finally onto said coolant (140);
e. wherein said cooling volume (306) is configurable so as to determine the static cooling capacity of said device (300) defined when said coolant (140) is in a static non-flowing state.

2. The device of claim 1 wherein said cooling volume (306) is configured to be proportional to both the heat generated directly or indirectly by said body (110), and required minimal static cooling time.

3. The device of claim 1 wherein said heat exchanging surface (308) and at least a portion of said body (110) are composed of a high heat conducting material.

4. The device of claim 3 wherein said high heat conducting material comprises at least one or more materials selected from: a metal, a metallic alloy, aluminum, an aluminum alloy, copper, a copper alloy, silver, silver alloy, gold, gold alloy, platinum, platinum alloy, nickel, nickel alloy, titanium alloy, titanium alloy, graphene, a polymer, polymeric alloys, shape memory materials, shape memory polymers, shape memory metallic alloys, electroactive polymers, magnetostrictive materials, photosensitive materials, materials sensitive to magnetic field, materials sensitive to an electric field, materials sensitive to electromagnetic radiation, materials sensitive to light, material sensitive to specific wavelength, or any combination thereof.

5. The device of claim 1 wherein the heat capacity of said cooling device (300) is configurable according to at least one parameter selected from:
a. the functional temperature range of a heat generating load;
b. required static cooling capacity;
c. required minimal static cooling time;
d. required static cooling temperature range;
e. functional temperature range;
f. minimum temperature;
g. maximum temperature;
h. coolant circulation flow rate;
i. coolant type;
j. non-circulation time frame;
k. any combination thereof.

6. The device of claim 1 wherein said coupling interface (310) is further fit with a position control module (115) provided for controlling the proximity or the pressure applied between said body (110) and said heat exchanging surface (308) for improving heat conduction therebetween.

7. The device of claim 6 wherein said position control module (115) is provided with at least one or more selected from:
a. an actuator;
b. a linear actuator;
c. a piezoelectric actuator;
d. a remotely controllable actuator that may be controlled with a remote wireless control signal;
e. a coupling assembly comprising male and female couplers;
f. a coupling assembly comprising a nut and bolt;
g. a magnetic coupling assembly;
h. an inflatable balloon assembly;
i. a remotely controllable inflatable balloon assembly wherein the volume of said inflatable balloon is controllable with a remote wireless control signal;
j. any combination thereof.

8. The device of claim 6 wherein said position control module (115) is positioned on either one or both of said body (110) or said heat exchanging surface (308).

9. The device of claim 1 further comprises a construct coupling interface (312) that provides for coupling said device (300) to auxiliary constructs (320) or device selected from: a shelf, a wall, a support beam, a supporting structure, a support member, a framework, a second cooling device (300), an automated storage and retrieval system, or any combination thereof.

10. A cooling assembly (350) comprising at least two cooling devices (300) according to claim 6 wherein a first cooling device (300a) is coupled to an oppositely facing second cooling device (300b) over a distance (352) wherein each of the heat exchanging surfaces (308) are configured to be facing one another across said distance (352); wherein each of said heat exchange surfaces (308) is associated with a body (110); and wherein each pair of oppositely facing bodies (110) are associated with a common positioning module (115) provided to urge each of said bodies (100) toward its respective heat exchanging surface (308).

11. The apparatus of claim 10 wherein said body (110) is configured to be moveable along said heat exchanging surface (308) about an axis that is orthogonal to the axis formed by said distance (352).

12. The apparatus of claim 1 wherein a plurality of said cooling devices (300) are utilized to form a construct forming at least one open volume chamber (102) having at least one open face (109), wherein said chamber (102) forms a sealed liquid free zone with at least one heat exchanging surface (308), and wherein said chamber (102) houses said body (110) that is configured to be moveable along said at least two inner surfaces (108i) and wherein said body (110) is introduced into said chamber (102) through said open face (109, 351).

13. The apparatus of claim 12 wherein said body (110) is sized so as to be receivable and movable along the length of said chamber (102).

14. The apparatus of claim 13 wherein at least one surface of said body (110) is configured to be in contact with said internal surface (108i).

15. The apparatus of claim 14 wherein said body (110) is configured to fit within said volume (102) wherein said body has at least four surfaces forming a trapezoidal box configuration (210) wherein at least two side walls (212) are provided at a first angle (214), and wherein at least two of said side walls are configured to be heat conducting surfaces that are in contact with said internal surface (108i, 308) to facilitate heat conduction and to generate pressure along at least a portion of said side walls, wherein said first angle (214) is defined between a front face having a first dimension d1 and a back face having a second dimension d2 configured such that d1>d2.

16. The apparatus of claim 15 wherein at least four side walls are provided at an angle such that said body (110) forms a trapezoidal prism (210p), having a first face (210a) having dimensions (d1, d4) and a second face (210b) having dimensions (d2, d3) configured wherein d1>d2, define a first angle (214) and d4>d3 define a second angle (216).

17. The apparatus (100) of claim 12 wherein said volume (102) comprises at least two of said body (110a, 110b) wherein each is associated with an individual heat generating load (50) along a surfaces therein defining two heat generating bodies and wherein at least one position control module (115) is disposed between said two heat generating bodies; wherein said position control module (115) is provided for controlling the position of said two heat generating bodies within said chamber (102) and for improving heat conduction between said internal surface (108i, 308) and said sliding moveable body (110).

18. The device of claim 1 wherein indirect heat generation is provided wherein said body (110) is associated with at least one heat generating load (50).

19. The device of claim 18 wherein said body (110) has a second face (114) for associating with a heat generating load (50) and a first face (112) providing a heat exchange surface, wherein said first face is in continuous heat exchanging contact with said heat exchanging surface (308); and wherein a positioning module (115) provides for urging said second face (112) onto said heat exchange surface (308) for improving heat conduction therebetween.

20. The device of claim 1 wherein said body (110) and said heat exchanging surface (308) are configured to be in contact with one another utilizing corresponding male and female surface configurations.

21. The device of claim 1 wherein at least one surface of said body (110) corresponds to at least one surface of said heat exchanging surface (308) characterized in that said corresponding surfaces are provided with an interlacing configuration having a configurable surface area.

22. A cooling device assembly (100), comprising:
a. a housing (108) having an external surface (108e) and an internal surface (108i) defining therebetween a continuous cooling volume (108c), wherein a high heat capacity liquid phase coolant (140) is disposed within said continuous cooling volume (108c);
b. wherein said coolant (140) flows within said cooling volume (108c) with a coolant flowing interface (105) featuring an inlet (105i) and an outlet (105o) for circulating said coolant (140);
c. wherein said internal surface (108i) forms at least one internal volume chamber (102) having at least one open face (109), said chamber (102) is configured to be a sealed liquid free zone for housing a sliding moveable body (110) receivable through said open face (109);
d. wherein at least a portion of said sliding moveable body (110) is configured to be in continuous heat exchanging contact with at least one surface of said internal surface (108i);
e. wherein heat generated directly or indirectly by said sliding moveable body (110) is conducted toward at least one surface of said internal surface (108i) and finally onto said coolant (140); and
f. wherein said cooling volume (108c) is characterized to be configurable so as to determine the static cooling capacity defined when said coolant (140) is in a static non-flowing state.

23. The apparatus of claim 22 wherein said cooling volume (108c) is configured to be proportional to both the heat generated directly or indirectly by said body (110), and the required minimal static cooling time.

24. The apparatus of claim 22 wherein the heat capacity of said cooling device (100) is customizable by configuring at least one parameter selected from:
a. said cooling volume (108c);
b. the configuration of said internal surface (108i);
c. the shape of said internal volume (102);
d. the volume of said internal volume (102);
e. at least one dimension of said internal volume (102);
f. any combination thereof.

25. The apparatus of claim 22 further comprises a position control module (115) provided for controlling the proximity or the pressure applied between said body (110) and said internal surface (108i) for improving heat conduction therebetween.

26. The apparatus of claim 24 wherein said volume (102) comprises two of said body (110a, 110b) wherein each is associated with an individual heat generating load (50) along a first surface therein defining two heat generating bodies and wherein at least one position control module (115) is disposed between said two heat generating bodies, said position control module (115) provides for controlling the position of said two heat generating bodies within said chamber (102) and for improving heat conduction between said internal surface (108i, 308) and said two of said body (110, 110a, 110b).

27. A cooling system including the cooling device of claim 1 that is further coupled to an auxiliary coolant circulating system (15) along said coolant circulating interface (105) so as to allow the flow of said coolant (140) between said inlet (105i) and said outlet (105o).

28. A cooling system including the cooling device of claim 22 that is further coupled to an auxiliary coolant circulating system (15) along said coolant circulating interface (105) so as to allow the flow of said coolant (140) between said inlet (105i) and said outlet (105o).

29. The device of claim 1 wherein said high heat capacity coolant (140) is selected from at least one of: double distilled water, natural water, sea-water, fresh-water, recycled water, filtered water, water based liquid, liquid, chemical, compound, high heat capacity liquid, high heat capacity plasma, high heat capacity emulsion, high heat capacity viscous fluid, high heat capacity mixture, high heat capacity colloid, and any combination thereof.

30. The apparatus of claim 22 wherein said high heat capacity coolant (140) is selected from at least one of: double distilled water, natural water, sea-water, fresh-water, recycled water, filtered water, water based liquid, liquid, chemical, compound, high heat capacity liquid, high heat capacity plasma, high heat capacity emulsion, high heat capacity viscous fluid, high heat capacity mixture, high heat capacity colloid, and any combination thereof.
